(19) United States
(12) Patent Application Publication
(10) Pub. No.: US 2025/0089537 A1
(43) Pub. Date: Mar. 13, 2025

(54) DISPLAY PANEL AND MANUFACTURING METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zeyu LI, Beijing (CN); Mingjiong ZHANG, Beijing (CN); Taofeng XIE, Beijing (CN); Min HE, Beijing (CN); Shaolin ZHU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/728,121

(22) PCT Filed: Feb. 22, 2023
(86) PCT No.: PCT/CN2023/077734

§ 371 Date: Jul. 11, 2024

(30) Foreign Application Priority Data
Apr. 8, 2022 (CN) 202210369350.X

(51) Int. Cl. H10K 59/80; H10K 59/12; H10K 59/40; H10K 102/00

(52) U.S. Cl. CPC H10K 59/878; H10K 59/1201; H10K 59/40; H10K 59/873; H10K 59/879; H10K 2102/351

(57) ABSTRACT

A display panel includes a display substrate, a light extraction layer, and a first planarization layer. The light extraction layer is arranged on a light emitting side of the display substrate, and comprises a plurality of first recesses. The first planarization layer is arranged on one side of the light extraction layer away from the display substrate. The refractive index of the first planarization layer is greater than the refractive index of the light extraction layer, and the thickness of the first planarization layer is 1.5 to 5 times the thickness of the light extraction layer.

### CROSS-REFERENCE TO RELATED APPLICATIONS

The present application is a national phase application of International Application No. PCT/CN2023/077734, filed on Feb. 22, 2023, which is based upon and claims priority to Chinese Patent Application No. 202210369350.X, entitled “DISPLAY PANEL AND MANUFACTURING METHOD THEREOF, AND DISPLAY DEVICE”, filed on Apr. 8, 2022, and the entire contents thereof are incorporated herein by reference.

### TECHNICAL FIELD

The present disclosure relates to the field of display technology, and in particular, to a display panel, a method for manufacturing the display panel, and a display device including the display panel.

### BACKGROUND

With the develop of science and technology and the improvement of social living standards, consumers have increasing requirements for display products. For display manufacturers, it is a definite development direction to produce display produce having high image quality and low power consumption. Also, bendable flexible display devices are favored by consumers.

It should be noted that, information disclosed in the above background portion is provided only for better understanding of the background of the present disclosure, and thus it may contain information that does not form the prior art known by those ordinary skilled in the art.

### SUMMARY

The objective of the present disclosure is to provide a display panel with high light extraction efficiency and easier bending, a method for preparing the display panel, and a display device including the display panel.

According to one aspect of the present disclosure, there is provided a display panel, including:
a display substrate including a plurality of sub-pixels;
a light extraction layer, disposed on a light emitting side of the display substrate, the light extraction layer including a plurality of first grooves; and
a first planarization layer, disposed on a side of the light extraction layer away from the display substrate, wherein a refractive index of the first planarization layer is greater than a refractive index of the light extraction layer, and a thickness of the first planarization layer is 1.5 to 5 times greater than a thickness of the light extraction layer.

In an exemplary embodiment of the present disclosure, a flatness of a surface of the first planarization layer away from the display substrate is greater than or equal to 85%.

In an exemplary embodiment of the present disclosure, the first planarization layer includes a plurality of second grooves, the sub-pixel is covered by an orthographic projection of the first groove on the display substrate, and an orthographic projection of the second groove on the display substrate is at least partially overlapped with the orthographic projection of the first groove on the display substrate.

In an exemplary embodiment of the present disclosure, a height in a second direction of a groove sidewall of the first groove is increased with the increasing distance in a first direction from the center of the sub-pixel; and a height in the second direction of a groove sidewall of the second groove is increased with the increasing distance in the first direction from the center of the sub-pixel; wherein the second direction is perpendicular to a display surface of the display substrate, and the first direction is parallel to the display surface of the display substrate.

In an exemplary embodiment of the present disclosure, the groove sidewall of the first groove includes a curved surface, the groove sidewall of the second groove includes a curved surface, and a curvature radius of the groove sidewall of the first groove is smaller than a curvature radius of the groove sidewall of the second groove.

In an exemplary embodiment of the present disclosure, the groove sidewall of the first groove includes a first portion, a second portion and a third portion which are smoothly connected in sequence, the first portion is closer to the display substrate than the third portion, the first portion and the third portion are configured as arc surfaces, and the second portion is configured as an inclined surface; and the groove sidewall of the second groove includes a fourth portion, a fifth portion and a sixth portion which are smoothly connected in sequence, the fourth portion is closer to the display substrate than the sixth portion, the fifth portion is configured as an inclined surface, and the fourth portion and the sixth portion are configured as arc surfaces.

In an exemplary embodiment of the present disclosure, an inclination angle of the second portion is greater than an inclination angle of the fifth portion.

In an exemplary embodiment of the present disclosure, the groove sidewall of the first groove is configured as an inclined surface, the groove sidewall of the second groove is configured as an inclined surface, and an inclination angle of the groove sidewall of the first groove is greater than an inclination angle of the groove sidewall of the second groove.

In an exemplary embodiment of the present disclosure, an orthographic projection of the groove sidewall of the first groove on the display substrate is located within an orthographic projection of the groove sidewall of the second groove on the display substrate; and
a bottom wall of the first groove is a plane, a bottom wall of the second groove is a plane, the sub-pixel is covered by an orthographic projection of the bottom wall of the second groove on the display substrate, and the orthographic projection of the bottom wall of the second groove on the display substrate is located within an orthographic projection of the bottom wall of the first groove on the display substrate.

In an exemplary embodiment of the present disclosure, a depth of the first groove is greater than a depth of the second groove.

In an exemplary embodiment of the present disclosure, a thickness of the first planarization layer at the second groove is greater than a thickness of a portion of the first planarization layer opposite to the light extraction layer.

In an exemplary embodiment of the present disclosure, the first groove is configured as a via hole penetrating the light extraction layer.

In an exemplary embodiment of the present disclosure, the display substrate includes a display area and a peripheral area connected to the display area, the peripheral area includes a non-display area, a bending area and a binding area connected in sequence, and the light extraction layer and the first planarization layer are both arranged in the display area and the non-display area.

In an exemplary embodiment of the present disclosure, at least two isolation dams are disposed in the non-display area and surround the display area, and the isolation dams are covered by the light extraction layer and the first planarization layer.

In an exemplary embodiment of the present disclosure, in the non-display area, a distance between an edge of the light extraction layer away from the display area and an edge of the first planarization layer away from the display area is less than 1 micrometer.

In an exemplary embodiment of the present disclosure, the light extraction layer and the first planarization layer include same organic material.

In an exemplary embodiment of the present disclosure, the organic material includes propylene glycol methyl ether acetate.

In an exemplary embodiment of the present disclosure, the organic material further includes an acrylate monomer.

In an exemplary embodiment of the present disclosure, the material of the first planarization layer includes propylene glycol methyl ether acetate, acrylate monomer, zirconium dioxide particles, 1-methoxy-2-propanol, (3-methoxy-1-butyl) acetate, metal oxide particles, photoinitiator, coupling agent and additives.

In an exemplary embodiment of the present disclosure, weight proportions of respective materials of the first planarization layer are: 20 to 30 parts of propylene glycol methyl ether acetate, 1 to 10 parts of acrylate monomer, 20 to 30 parts of zirconium dioxide particles, 10 to 20 parts of 1-methoxy-2-propanol, 10 to 20 parts of (3-methoxy-1-butyl) acetate, 0.1 to 3 parts of metal oxide particles, 0.1 to 3 parts of photoinitiator, 1 to 5 parts of coupling agent, and 1 to 10 parts of additives.

In an exemplary embodiment of the present disclosure, a refractive index of the first planarization layer is greater than or equal to 1.6 and less than or equal to 1.75, and a refractive index of the light extraction layer is greater than or equal to 1.4 and less than or equal to 1.55.

In an exemplary embodiment of the present disclosure, a transmittance of the light extraction layer is greater than a transmittance of the first planarization layer.

In an exemplary embodiment of the present disclosure, a transmittance of the first planarization layer is greater than or equal to 90%, and a modulus of the first planarization layer is greater than or equal to 1000 KPa.

In an exemplary embodiment of the present disclosure, the display panel further includes:
an encapsulation layer group, disposed on the light emitting side of the display substrate; and
a touch layer group, disposed on a side of the encapsulation layer group away from the display substrate;
wherein, one layer in the encapsulation layer group or the touch layer group is multiplexed as the light extraction layer, and one layer in the encapsulation layer group or the touch layer group is multiplexed as the first planarization layer.

In an exemplary embodiment of the present disclosure, the touch layer group includes:
a first touch metal layer, disposed on the light emitting side of the display substrate;
a touch insulating layer, disposed on a side of the first touch metal layer away from the display substrate;
a second touch metal layer is disposed on a side of the touch insulating layer away from the display substrate; and
a protective layer, disposed on a side of the second touch metal layer away from the display substrate;
wherein, the touch insulating layer is multiplexed as the light extraction layer.

In an exemplary embodiment of the present disclosure, the protective layer is multiplexed as the light extraction layer, or the protective layer is multiplexed as the first planarization layer.

In an exemplary embodiment of the present disclosure, a touch pattern is formed by the first touch metal layer and the second touch metal layer, the touch pattern includes a plurality of metal lines, a gap is provided between two adjacent first grooves, and an orthographic projection of the metal line on the display substrate is located within an orthographic projection of the gap on the display substrate.

In an exemplary embodiment of the present disclosure, the display panel further includes:
a color filter layer, disposed on the light emitting side of the display substrate, wherein the color filter layer includes a black matrix and a filter portion, and the black matrix is multiplexed as the light extraction layer.

In an exemplary embodiment of the present disclosure, the display panel further includes:
a second planarization layer, disposed on a side of the first planarization layer away from the display substrate, and a side of the second planarization layer away from the display substrate is a plane.

In an exemplary embodiment of the present disclosure, the display panel further includes:
an adhesive layer, disposed on the side of the first planarization layer away from the display substrate, the adhesive layer being multiplexed as the second planarization layer; and
a cover plate, disposed on a side of the adhesive layer away from the display substrate.

According to another aspect of the present disclosure, there is provided a method for manufacturing display panel, including:
forming a display substrate, the display substrate including a plurality of sub-pixels;
forming a light extraction layer on a light exiting side of the display substrate, wherein the light extraction layer includes a plurality of first grooves; and
forming a first planarization layer on a side of the light extraction layer away from the display substrate, a refractive index of the first planarization layer is greater than a refractive index of the light extraction layer, and a thickness of the first planarization layer is 1.5 to 5 times greater than a thickness of the light extraction layer.

In an exemplary embodiment of the present disclosure, forming the first planarization layer on the side of the light extraction layer away from the display substrate includes:
forming a first planarization material layer on the side of the light extraction layer away from the display substrate, and photoetching the first planarization material layer to form the first planarization layer.

In an exemplary embodiment of the present disclosure, a liquid viscosity of the first planarization material layer is less than or equal to 5 cp.

In an exemplary embodiment of the present disclosure, forming the light extraction layer on the light emitting side of the display substrate includes:
forming a light extraction material layer on a light emitting side of the display substrate, and photoetching the light extraction material layer to form the light extraction layer.

In an exemplary embodiment of the present disclosure, a liquid viscosity of the light extraction material layer is less than or equal to 5 cp.

According to yet another aspect of the present disclosure, there is provided a display device, including: any of the above display panel.

It is to be understood that both the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and are used together with the specification to explain the principles of the present disclosure. Obviously, the accompanying drawings described below are only some embodiments of the present disclosure, and for those of ordinary skill in the art, other accompanying drawings can be obtained based on these accompanying drawings without creative effort.

FIG. 1 is a schematic structural diagram of a first exemplary embodiment of a display panel according to the present disclosure.

FIG. 2 is a schematic diagram of a top view of the first groove, the second groove and the sub-pixel in FIG. 1.

FIG. 3 is a schematic diagram of a light path of the display panel in FIG. 1.

FIG. 4 is a schematic structural diagram of a second exemplary embodiment of a display panel according to the present disclosure.

FIG. 5 is a schematic diagram of a light path of the display panel in FIG. 4.

FIG. 6 is a schematic diagram of the area division structure of the display panel of the present disclosure.

FIG. 7 is a schematic diagram of the structure of the display panel in the non-display area of the present disclosure.

FIG. 8 is a schematic structural diagram of a third exemplary embodiment of a display panel according to the present disclosure.

FIG. 9 is a schematic structural diagram of a fourth exemplary embodiment of a display panel according to the present disclosure.

FIG. 10 is a schematic structural diagram of a fifth exemplary embodiment of a display panel according to the present disclosure.

FIG. 11 is a schematic structural diagram of a sixth exemplary embodiment of a display panel according to the present disclosure.

FIG. 12 is a schematic structural diagram of a seventh exemplary embodiment of a display panel according to the present disclosure.

FIG. 13 is a schematic structural diagram of an eighth exemplary embodiment of a display panel according to the present disclosure.

FIG. 14 is a schematic flow chart of a method for manufacturing display panel according to the present disclosure.

FIG. 15 to FIG. 18 are schematic diagrams of the structures of the respective steps for preparing the display panel in FIG. 8.

### DESCRIPTION OF REFERENCE NUMERALS

1. base substrate; 2. light shielding layer; 3. buffer layer;
4. active layer; 41. conductor portion; 42. channel portion;
5. gate insulating layer; 6. gate electrode;
7. interlayer dielectric layer; 71. first via hole;
81. source electrode; 82. drain electrode;
9. passivation layer; 91. second via hole;
10. first electrode;
11. pixel definition layer; 111. third via hole;
12. light-emitting layer group; 13. second electrode;
14. encapsulation layer group; 140. encapsulation base layer; 141. first encapsulation layer;
142. second encapsulation layer; 143. third encapsulation layer;
15. touch layer group; 151. first touch metal layer; 152. touch insulating layer; 153. second touch metal layer; 154. protective layer;
16. adhesive layer; 17. cover plate;
18. light extraction layer; 181. first groove; 1811. first inner ring line; 1812. first outer ring line;
1813. first part; 1814. second part; 1815. third part; 182. light extraction material layer;
19. first planarization layer; 191. second groove; 1911. second inner ring line; 1912. second outer ring line; 1913. fourth part; 1914. fifth part; 1915. sixth part;
20. sub-pixel; 21. photoresist;
22. mask plate; 221. light shielding portion; 222. light transmitting portion;
23. second planarization layer;
24. color filter layer; 241. light filter; 242. black matrix;
25. isolation dam; 100. display substrate;
X, first direction; Y, second direction;
AA, display area; ZB, peripheral area; FA, non-display area; ZW, bending area; BOD, binding.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed descriptions will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; and the terms “first”, “second” and “third” etc. are used merely as labels and are not intended to limit the quantity of their objects.

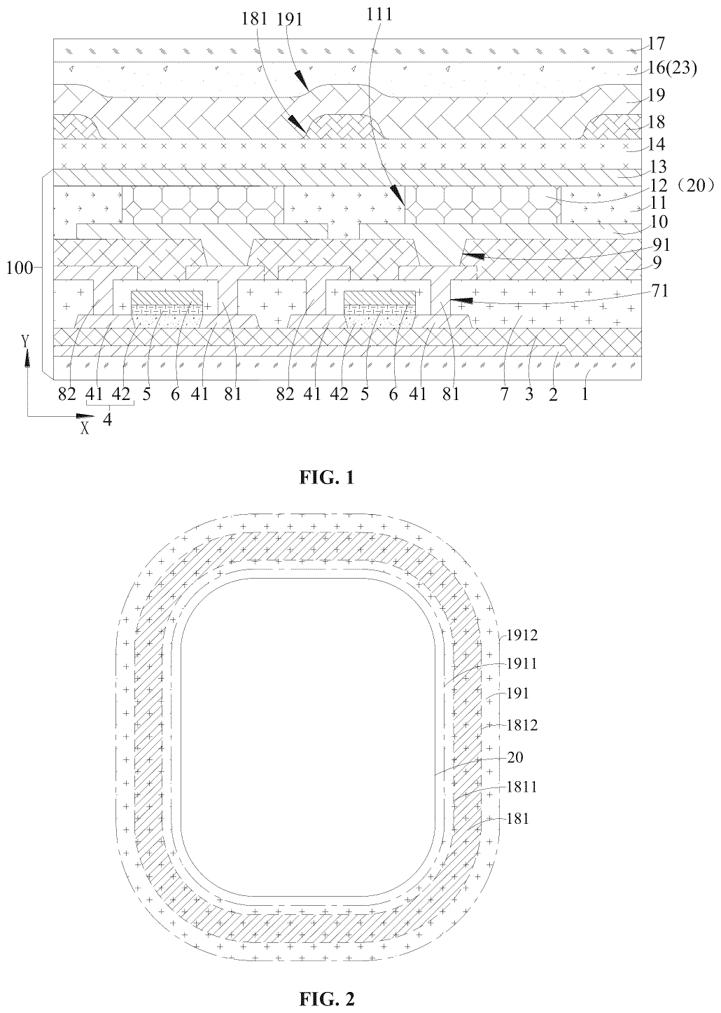

An example embodiment of the present disclosure provides a display panel, as shown in FIG. 1, the display panel may include a display substrate 100, a light extraction layer 18 and a first planarization layer 19; the display substrate 100 may include a plurality of sub-pixels 20; the light extraction layer 18 is disposed on the light emitting side of the display substrate 100, and the light extraction layer 100 may include a plurality of first grooves 181; the first planarization layer 19 is disposed on a side of the light extraction layer 18 away from the display substrate 100, the refractive index of the first planarization layer 19 is greater than the refractive index of the light extraction layer 18, and the thickness of the first planarization layer 19 is 1.5 to 5 times greater than the thickness of the light extraction layer 18.

In the display panel disclosed in the present invention, the interface between the first planarization layer 19 and the side wall of the first groove 181 is a total reflection surface. The side wall of the first groove 181 will cause the inclined outgoing light to undergo total reflection to form total reflection light, change the angle of the outgoing light, so that the total reflection light is more converged and emitted from the front of the display panel, thereby improving the light output efficiency of the front of the display panel. Therefore, under the same brightness requirement, the power consumption of the display panel can be reduced; the output efficiency of the light to the side of the display panel can be reduced to increase the anti-peeping effect; and it can reduce cross-color and improve the display effect; the first planarization layer 19 is thinner and easier to bend, which can meet the bending requirements of the flexible display panel, so that the display panel is suitable for a bendable flexible display device.

The display substrate 100 can be an OLED (Organic Electroluminescence Display) display substrate, a QLED (Quantum Dot Light Emitting Diodes) display substrate, etc. The display substrate 100 has a light-emitting side and a non-light-emitting side, the light-emitting side and the non-light-emitting side are arranged opposite to each other, and an image can be displayed on the light-emitting side, and the side that displays the image is the display surface. The OLED display substrate 100 has the characteristics of self-luminescence, high brightness, wide viewing angle, fast response time, and the ability to produce R, G, B full-color components, etc., so it is regarded as a star product of the next-generation display.

The following description will be made using OLED as an example.

The display substrate 100 may include a driving backplane and a light emitting device. The driving backplane may include a driving circuit. The driving circuit may drive the light emitting device to emit light.

In this example embodiment, the driving backplane may include a substrate 1, and the material of the substrate 1 may include an inorganic material, for example, the inorganic material may be glass, quartz or metal. The material of the substrate 1 may also include an organic material, for example, the organic material may be a resin material such as polyimide, polycarbonate, polyacrylate, polyetherimide, polyethersulfone, polyethylene terephthalate and polyethylene naphthalate. The substrate 1 may be formed by a plurality of material layers, for example, the substrate 1 may include a plurality of base layers, and the material of the base layers may be any of the above materials. Of course, the substrate 1 may also be configured as a single layer, which may be any of the above materials.

A shading layer 2 can also be formed on one side of the base substrate 1. The light incident from the base substrate 1 into the active layer 4 will generate photogenerated carriers in the active layer 4, which will have a huge impact on the characteristics of the thin film transistor, and ultimately affect the display quality of the display device; the shading layer 2 can block the light incident from the base substrate 1, thereby avoiding affecting the characteristics of the thin film transistor and avoiding affecting the display quality of the display device.

A buffer layer 3 can also be formed on the side of the light-shielding layer 2 away from the base substrate 1. The buffer layer 3 serves to block water vapor and impurity ions in the base substrate 1 (especially organic materials), and serves to add hydrogen ions to the subsequently formed active layer 4. The buffer layer 3 is made of insulating material, which can insulate and isolate the light-shielding layer 2 from the active layer 4.

An active layer 4 is provided on the side of the buffer layer 3 away from the substrate 1. The active layer 4 may include a channel portion 42 and conductor portions 41 provided at both ends of the channel portion 42. A gate insulating layer 5 is provided on the side of the active layer 4 away from the substrate 1. A gate 6 is provided on the side of the gate insulating layer 5. An interlayer dielectric layer 7 is provided on the side of the gate 6 away from the substrate 1. A first via 71 is provided on the interlayer dielectric layer 7. The first via 71 is connected to the conductor portion 41. A source 81 and a drain 82 are provided on the side of the interlayer dielectric layer 7 away from the substrate 1. The source 81 and the drain 82 are connected to the two conductor portions 41 through two first vias 71, respectively. A passivation layer 9 is provided on the side of the source 81 and the drain 82 away from the substrate 1. A second via 91 is provided on the passivation layer 9. The second via 91 is connected to the source 81. A thin film transistor is formed by the active layer 4, the gate 6, the source 81 and the drain 82.

It should be noted that the thin film transistor described in this specification is a top-gate thin film transistor. In other exemplary embodiments of the present disclosure, the thin film transistor may also be a bottom-gate type or a dual-gate type, and its specific structure will not be described in detail here. Moreover, in the case of using thin film transistors with opposite polarities or when the current direction changes during circuit operation, the functions of the “source 81” and the “drain 82” are sometimes interchanged. Therefore, in this specification, the “source 81” and the “drain 82” may be interchanged.

A light emitting device is disposed on a side of the passivation layer 9 away from the base substrate 1. The light emitting device may include a first electrode 10, a pixel definition layer 11, a light emitting layer group 12 and a second electrode 13.

Specifically, a first electrode 10 is disposed on a side of the passivation layer 9 away from the base substrate 1. The first electrode 10 is connected to the source electrode 81 of the driving backplane through a second via hole 91. The first electrode 10 may be an anode.

A pixel definition layer 11 is disposed on the side of the first electrode 10 away from the base substrate 1, a third via hole 111 is disposed on the pixel definition layer 11, and a light-emitting layer group 12 is disposed in the third via hole 111. A second electrode 13 is disposed on the side of the light-emitting layer group 12 away from the base substrate 1, the second electrode 13 may be a cathode, and the second electrode 13 is connected to the ground line VSS. The light-emitting layer group 12 in one third via hole 111 emits light to form one sub-pixel 20, so that the light-emitting layer group 12 in one third via hole 111 is one sub-pixel 20, so that the orthographic projection of the sub-pixel 20 on the display substrate 100 is the orthographic projection of the light-emitting layer group 12 on the display substrate 100, and the display substrate 100 may include a plurality of sub-pixels 20.

The light-emitting layer group 12 may include a hole injection layer, a hole transport layer, a light-emitting layer, an electron transport layer and an electron injection layer stacked in sequence, the hole injection layer is in contact with the first electrode 10, and the electron injection layer is in contact with the second electrode 13. Of course, in other exemplary embodiments of the present disclosure, the light-emitting layer group 12 may include only a hole transport layer, a light-emitting layer and an electron transport layer, and the light-emitting layer group 12 may also be other structures, and its specific structure may be configured as needed.

A light extraction layer 18 is disposed on the light emitting side of the display substrate 100, and the thickness of the light extraction layer 18 is greater than or equal to 1 micron and less than or equal to 3 microns. The light extraction layer 18 may include a plurality of first grooves 181, and the first grooves 181 may include groove side walls and groove bottom walls, the groove bottom walls are parallel to the display surface, and the groove side walls intersect with the display surface. The first grooves 181 correspond to the sub-pixels 20 one by one, specifically, the number of the first grooves 181 is the same as the number of the sub-pixels 20, and the shape of the first grooves 181 is the same as the shape of the sub-pixels 20, for example, the sub-pixels 20 are configured to be circular, and the first grooves 181 are also configured to be circular; the sub-pixels 20 are configured to be rectangular, and the first grooves 181 are also configured to be rectangular; of course, in other example embodiments of the present disclosure, the shapes of the sub-pixels 20 and the shapes of the first grooves 181 may also be other shapes, which are not described one by one here.

As shown in FIG. 2, the orthographic projection of the first groove 181 on the display substrate 100 covers the sub-pixel 20, that is, the edge of the orthographic projection of the first groove 181 on the display substrate 100 may coincide with the edge of the sub-pixel 20; or the orthographic projection of the sub-pixel 20 on the display substrate 100 may be located within the orthographic projection of the first groove 181 on the display substrate 100.

It should be noted that, since the side walls of the first groove 181 are inclined and the sub-pixel 20 is disposed in a plane, when compared with the sub-pixel 20, the range of the orthographic projection of the first groove 181 on the display substrate 100 refers to the orthographic projection of the side (bottom wall) of the first groove 181 close to the display substrate 100 on the display substrate 100, that is, the orthographic projection of the bottom wall of the first groove 181 on the display substrate 100 covers the sub-pixel 20; similarly, when compared with the sub-pixel 20, the range of the orthographic projection of the second groove 191 on the display substrate 100 refers to the orthographic projection of the side (bottom wall) of the second groove 191 close to the display substrate 100 on the display substrate 100, that is, the orthographic projection of the bottom wall of the second groove 191 on the display substrate 100 covers the sub-pixel 20.

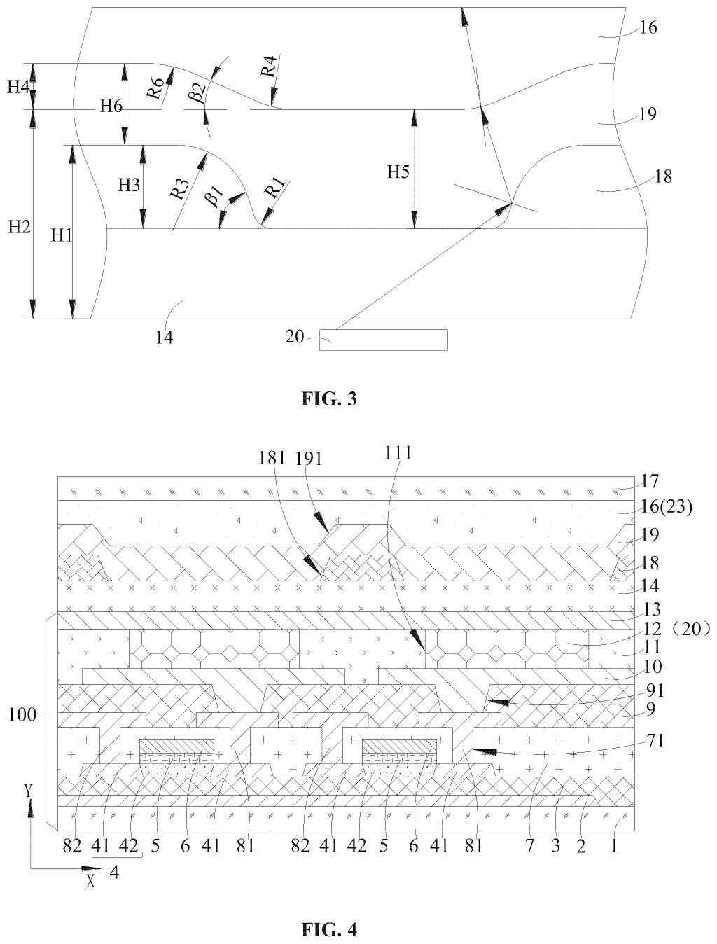

As shown in FIG. 3, the first planarization layer 19 is disposed on the side of the light extraction layer 18 away from the display substrate 100, and a part of the first planarization layer 19 is disposed in the first groove 181. The refractive index of the first planarization layer 19 is greater than the refractive index of the light extraction layer 18. Therefore, total reflection will easily occur at the interface between the first planarization layer 19 and the side wall of the first groove 181. The side wall of the first groove 181 will cause the inclined outgoing light to be totally reflected to form totally reflected light, change the angle of the outgoing light, so that the totally reflected light is more converged and emitted from the front of the display panel, thereby improving the light output efficiency of the front of the display panel, reducing the output efficiency of the light to the side of the display panel, and increasing the anti-peeping effect.

The main function of the first planarization layer 19 also includes planarizing the light extraction layer 18. If the thickness of the first planarization layer 19 is too thin, the light extraction layer 18 cannot be planarized. If the thickness of the first planarization layer 19 is too thick, the display panel will be difficult to bend, which is not suitable for a bendable flexible display device.

The thickness of the first planarization layer 19 may be 1.5 to 5 times of the thickness of the light extraction layer 18. For example, the thickness of the first planarization layer 19 may be greater than or equal to 2 microns and less than or equal to 5 microns. Further, the thickness of the first planarization layer 19 may be 1.67 to 2.5 times greater than the thickness of the light extraction layer 18. Specifically, for example, the thickness of the first planarization layer 19 may be 1.8 times, 2 times, 1.3 times, and so on, greater than the thickness of the light extraction layer 18. The first planarization layer 19 is thinner and easier to bend, which can meet the bending requirements of the flexible display panel, so that the display panel is suitable for a bendable flexible display device.

In the present disclosure, the flatness of the side of the first planarization layer 19 away from the display substrate 100 may be greater than or equal to 85%, for example, 88%, 89%, etc.; further, the flatness of the side of the first planarization layer 19 away from the display substrate 100 may be greater than or equal to 90%, for example, 92%, 93%, 96%, etc. The first planarization layer 19 is not only thin, but also can achieve the effect of planarizing the light extraction layer 18.

The flatness of one side of the first planarization layer 19 away from the display substrate 100 may be greater than or equal to 85%, so that the first planarization layer 19 may include a plurality of second grooves 191, and the second grooves 191 may include groove side walls and groove bottom walls, the groove bottom walls are parallel to the display surface, and the groove side walls intersect the display surface. The second grooves 191 correspond to the first grooves 181 one by one. The number of the first grooves 181 is the same as the number of the second grooves 191, and the shape of the first grooves 181 is the same as the shape of the second grooves 191, for example, the first groove 181 is configured to be circular, and the second groove 191 is also configured to be circular; the first groove 181 is configured to be rectangular, and the second groove 191 is also configured to be rectangular; of course, in other exemplary embodiments of the present disclosure, the shape of the second groove 191 and the shape of the first groove 181 can also be other shapes, which are not described one by one here.

Referring to FIG. 2, the orthographic projection of the second groove 191 on the display substrate 100 covers the orthographic projection of the first groove 181 on the display substrate 100, that is, the orthographic projection of the first groove 181 on the display substrate 100 is located within the orthographic projection of the second groove 191 on the display substrate 100, and the orthographic projection of the first groove 181 on the display substrate 100 may coincide with the orthographic projection of the second groove 191 on the display substrate 100; the orthographic projection of the first groove 181 on the display substrate 100 may also be located within the orthographic projection of the second groove 191 on the display substrate 100.

It should be noted that, since the groove side walls of the first groove 181 are inclined and the groove side walls of the second groove 191 are inclined, when comparing the first groove 181 and the second groove 191, the range of the orthographic projection of the first groove 181 on the display substrate 100 refers to the orthographic projection of the side of the first groove 181 away from the display substrate 100 (the opening of the first groove 181) on the display substrate 100, and the range of the orthographic projection of the second groove 191 on the display substrate 100 refers to the orthographic projection of the side of the second groove 191 away from the display substrate 100 (the opening of the second groove 191) on the display substrate 100.

Referring to FIG. 2, the orthographic projection of the groove sidewall of the first groove 181 on the display substrate 100 is annular, and the orthographic projection of the groove sidewall of the first groove 181 on the display substrate 100 has a first inner ring line 1811 and a first outer ring line 1812; the orthographic projection of the groove sidewall of the second groove 191 on the display substrate 100 is annular, and the orthographic projection of the groove sidewall of the second groove 191 on the display substrate 100 has a second inner ring line 1911 and a second outer ring line 1912; the orthographic projection of the groove sidewall of the first groove 181 on the display substrate 100 is located within the orthographic projection of the groove sidewall of the second groove 191 on the display substrate 100, that is, the orthographic projection of the groove sidewall of the first groove 181 on the display substrate 100 can overlap with the orthographic projection of the groove sidewall of the second groove 191 on the display substrate 100, that is, the first inner loop line 1811 overlaps with the second inner loop line 1911, and the first outer loop line 1812 overlaps with the second outer loop line 1912; or, the edge of the orthographic projection of the groove sidewall of the first groove 181 on the display substrate 100 is located within the edge of the orthographic projection of the groove sidewall of the second groove 191 on the display substrate 100, that is, the first inner loop line 1811 and the first outer loop line 1812 are located between the second inner loop line 1911 and the second outer loop line 1912. Such an arrangement can ensure that the total reflected light emitted from the groove sidewall of the first groove 181 can substantially all be emitted to the groove sidewall of the second groove 191, and refracted at the groove sidewall of the second groove 191.

In addition, the bottom wall of the first groove 181 is a plane, the bottom wall of the second groove 191 is a plane, the orthographic projection of the bottom wall of the second groove 191 on the display substrate 100 covers the sub-pixel 20, and the orthographic projection of the bottom wall of the second groove 191 on the display substrate 100 is located within the orthographic projection of the bottom wall of the first groove 181 on the display substrate 100. That is, the sub-pixel 20, the first groove 181 and the second groove 191 are aligned, the area of the bottom wall of the second groove 191 is less than or equal to the area of the bottom wall of the first groove 181, and the area of the sub-pixel 20 is less than or equal to the area of the bottom wall of the second groove 191. In this arrangement, the outgoing light emitted from the sub-pixel 20 perpendicular to the display surface will not be totally reflected by the groove side wall of the first groove 181, nor will it be refracted by the groove side wall of the second groove 191, so as not to affect the overall display effect of the display panel.

As shown in FIG. 3, the side wall of the second groove 191 forms a refractive surface, and the total reflected light is refracted by the refractive surface to form refracted light, which changes the angle of the total reflected light so that the refracted light is basically perpendicular to the display surface of the display substrate 100, further improving the light output efficiency on the front of the display panel, reducing the light output efficiency on the side of the display panel, and increasing the anti-peeping effect; it can also reduce cross-color and improve the display effect.

The height in the second direction Y of the groove sidewall of the first groove 181 increases as the distance in the first direction X from the center of the sub-pixel 20 increases, and the height in the second direction Y of the groove sidewall of the second groove 191 increases as the distance in the first direction X from the center of the sub-pixel 20 increases. The second direction Y is perpendicular to the display surface of the display substrate 100. The first direction X is parallel to the display surface of the display substrate 100.

Referring to FIGS. 1, 3 and 14, in some example embodiments of the present disclosure, the groove sidewall of the first groove 181 may include a curved surface; the groove sidewall of the first groove 181 may include a first portion 1813, a second portion 1814 and a third portion 1815 which are smoothly connected in sequence, the first portion 1813 is closer to the display substrate 100 than the third portion 1815, the second portion 1814 is configured as an inclined surface, the first portion 1813 and the third portion 1815 are configured as arc surfaces, the first portion 1813 may be configured as a recessed shape, and the third portion 1815 may be configured as a protruding shape; specifically, the portion of the groove sidewall of the first groove 181 close to the display substrate 100 may be an arc surface, the middle portion of the groove sidewall of the first groove 181 may be configured as an inclined surface, and the portion of the groove sidewall of the first groove 181 away from the display substrate 100 may be an arc surface.

As shown in FIG. 1, FIG. 3 and FIG. 16, the groove sidewall of the second groove 191 may also include a curved surface; specifically, the portion of the groove sidewall of the second groove 191 close to the display substrate 100 may be an arc surface, and the arc surface may be configured as a concave shape; the portion of the groove sidewall of the second groove 191 away from the display substrate 100 may be an arc surface, and the arc surface may be configured as a protruding shape, and the two arc surfaces may be directly and smoothly connected, for example, the two arc surfaces may be directly tangentially connected; or there may be an inclined surface connected between the two arc surfaces, and the two arc surfaces are smoothly connected to the inclined surface. That is, the groove sidewall of the second groove 191 may include a fourth portion 1913, a fifth portion 1914 and a sixth portion 1915 which are smoothly connected in sequence, the fourth portion 1913 is closer to the display substrate 100 than the sixth portion 1915, the fifth portion 1914 is configured as an inclined surface, and the fourth portion 1913 and the sixth portion 1915 are configured as arc surfaces.

Referring to FIG. 3, the curvature radius R4 of the fourth portion 1913 and the curvature radius R6 of the sixth portion 1915 are both greater than the curvature radius R1 of the first portion 1813 and the curvature radius R3 of the third portion 1815, so that the curvature radius of the groove sidewall of the first groove 181 is smaller than the curvature radius of the groove sidewall of the second groove 191.

Referring to FIG. 3, the inclination angle β1 of the second portion 1814 is greater than the inclination angle β2 of the fifth portion 1914, so that the inclination angle of the groove sidewall of the first groove 181 is greater than the inclination angle of the groove sidewall of the second groove 191.

It should be noted that the above-mentioned inclination angles all refer to the angles with respect to the plane parallel to the display substrate 100.

Since the first planarization layer 19 is formed after the light extraction layer 18, the first planarization layer 19 has a certain planarization effect on the light extraction layer 18; therefore, the radius of curvature of the groove sidewall of the first groove 181 is smaller than the radius of curvature of the groove sidewall of the second groove 191, that is, the groove sidewall of the second groove 191 is relatively gentle, and the groove sidewall of the first groove 181 is relatively steep. The above-mentioned arc surface can also be an elliptical arc surface, a parabolic surface, etc. Of course, in other exemplary embodiments of the present disclosure, the groove sidewalls of the first groove 181 can also be formed by arc surfaces, elliptical arc surfaces, parabolic surfaces, etc.

In this exemplary embodiment, as shown in FIG. 3, the depth H3 of the first groove 181 is greater than the depth H4 of the second groove 191, that is, the depth H3 of the first groove 181 in the second direction Y is greater than the depth H4 of the second groove 191 in the second direction Y. Since the light extraction layer 18 is formed first and then the first planarization layer 19 is formed during the preparation process, the first planarization layer 19 has a certain planarization effect on the light extraction layer 18, so that the depth of the second groove 191 formed on the first planarization layer 19 is less than the depth of the first groove 181 formed on the light extraction layer 18.

The distance H2 between the plane where the bottom wall of the second groove 191 is located and the display substrate 100 is greater than the distance H1 between the side of the light extraction layer 18 away from the display substrate 100 and the display substrate 100; that is, the height H2 of the bottom wall of the second groove 191 in the second direction Y can be higher than the height H1 of the side of the light extraction layer 18 away from the display substrate 100 in the second direction Y.

The thickness H5 of the first planarization layer 19 at the second groove 191 is greater than the thickness H6 of the portion of the first planarization layer 19 opposite to the light extraction layer 18; that is, the distance H5 between the plane where the bottom wall of the second groove 191 is located and the plane where the bottom wall of the first groove 181 is located is greater than the distance H6 between the side of the first planarization layer 19 corresponding to the light extraction layer 18 away from the light extraction layer 18 and the light extraction layer 18. The material of the first planarization layer 19 has good fluidity, and since the first groove 181 is in a low-lying state, the material of the first planarization layer 19 will flow to the first groove 181, so that the first planarization layer 19 has a good planarization effect on the light extraction layer 18.

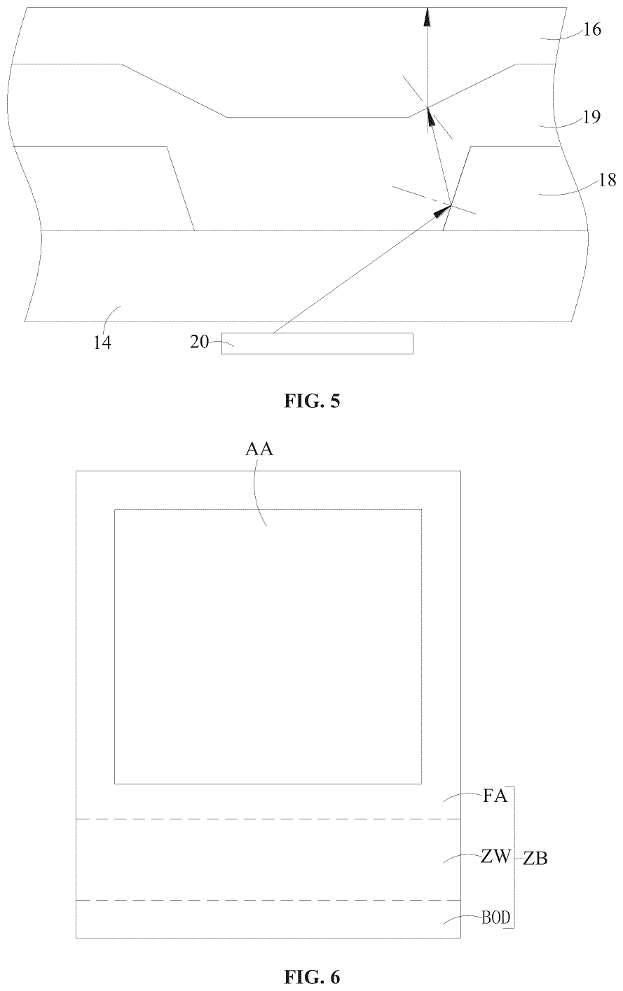

Referring to FIGS. 4 and 5, in some other exemplary embodiments of the present disclosure, the groove sidewall of the first groove 181 can be configured as an inclined surface, and the groove sidewall of the second groove 191 can be configured as an inclined surface. Since the first planarization layer 19 is formed after the light extraction layer 18, the first planarization layer 19 has a certain planarization effect on the light extraction layer 18; therefore, the inclination angle of the groove sidewall of the first groove 181 is greater than the inclination angle of the groove sidewall of the second groove 191.

Of course, in some other example embodiments of the present disclosure, the orthographic projection of the first groove 181 on the display substrate 100 may also cover a portion of the sub-pixel 20, and may also achieve the effect of converging a portion of the light from the sub-pixel 20; the orthographic projection of the second groove 191 on the display substrate 100 may cover a portion of the orthographic projection of the first groove 181 on the display substrate 100, and may also achieve the effect of converging a portion of the light that is totally reflected by the first groove 181.

In this example embodiment, the first groove 181 is configured as a via hole that penetrates the light extraction layer 18. The interface between the bottom wall of the first groove 181 and the first planarization layer 19 is prevented from forming a total reflection surface, which affects the light extraction efficiency. Of course, referring to FIG. 12, in some other example embodiments of the present disclosure, the first groove 181 can also be configured as a blind hole.

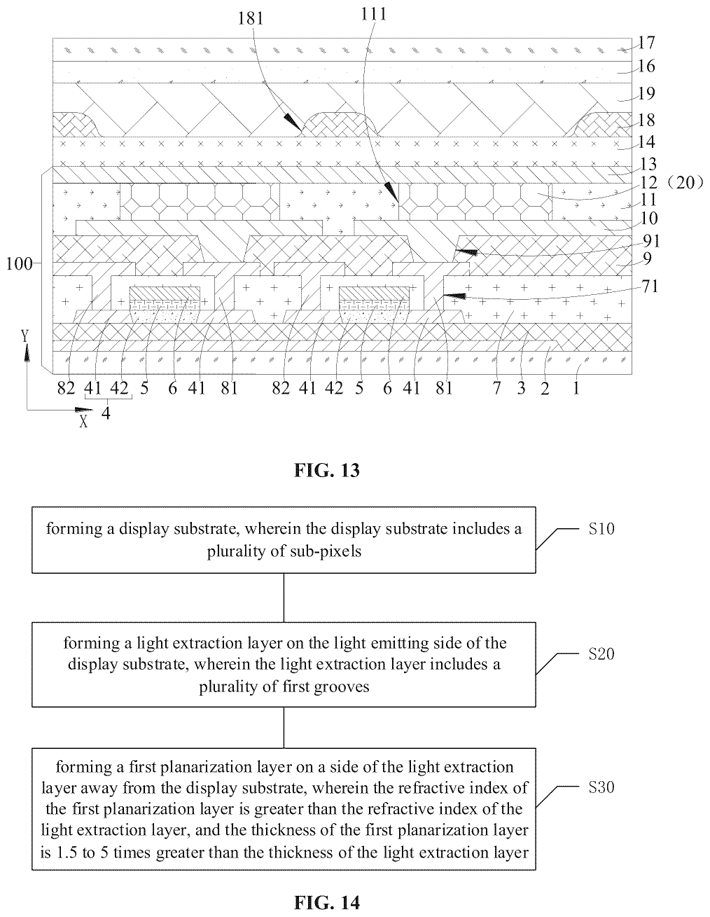

Of course, as shown in FIG. 13, in some other exemplary embodiments of the present disclosure, the first planarization layer 19 may be substantially formed as a plane on a side away from the display substrate 100, that is, the second groove 191 may not be formed in the first planarization layer 19.

The above is a specific description of the structure of the light extraction layer 18 and the first planarization layer 19 in the display area AA. The light extraction layer 18 and the first planarization layer 19 will be formed in the non-display area FA. Specifically, as shown in FIG. 6, the display substrate 100 may include a display area AA and a peripheral area ZW connected to the display area AA, the peripheral area ZW includes a non-display area FA, a bending area ZW and a binding area BOD connected in sequence, and the light extraction layer 18 and the first planarization layer 19 are both arranged in the display area AA and the non-display area FA. The light extraction layer 18 and the first planarization layer 19 are not arranged in the bending area ZW and the binding area BOD, which will not affect the bending performance of the bending area ZW, or the binding pins of the binding area BOD.

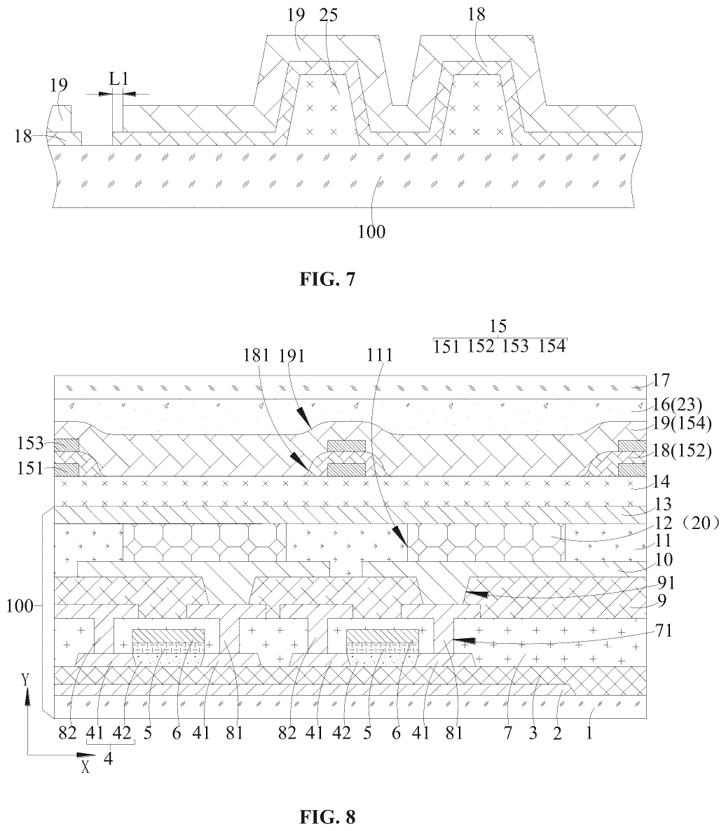

In addition, as shown in FIG. 7, at least two isolation dams 25 are disposed around the display area AA in the non-display area FA. The isolation dam 25 and the encapsulation layer group 14 are formed by the same graphic process. The isolation dam 25 can block external water vapor from entering the display area AA. The light extraction layer 18 and the first planarization layer 19 cover the isolation dam 25, further improving the sealing performance of the display panel and preventing external water vapor from entering the display area AA.

In addition, in the non-display area FA, the distance L1 between the edge of the light extraction layer 18 away from the display area AA and the edge of the first planarization layer 19 away from the display area AA is less than 1 micron. For example, the edge of the light extraction layer 18 may protrude from the edge of the first planarization layer 19, or the edge of the first planarization layer 19 may protrude from the edge of the light extraction layer 18.

Please refer to FIG. 7, when preparing a display panel, it is made on a motherboard, the motherboard includes a plurality of base substrates 1 arranged in an array, and the various layer structures of the plurality of display panels are prepared on the base substrates 1, and then the motherboard is cut to form a plurality of display panels. A gap is provided between the light extraction layer 18 and the first planarization layer 19 of two adjacent display panels on a motherboard, and the cutting can be carried out along the gap, that is, the light extraction layer 18 and the first planarization layer 19 do not need to be cut during cutting, and the gap can facilitate cutting the motherboard into a plurality of display panels.

In the present exemplary embodiment, the light extraction layer 18 and the first planarization layer 19 may include the same organic material. The organic material may include propylene glycol methyl ether acetate (PGMEA), and the organic material may further include an acrylate monomer.

Specifically, the material of the light extraction layer 18 may include propylene glycol methyl ether acetate, acrylate monomer, epoxy acrylate resin, photoinitiator and additives; wherein, propylene glycol methyl ether acetate is 70˜80 parts, acrylate monomer is 10˜20 parts, epoxy acrylate resin is 5˜15 parts, photoinitiator is 0.1˜3 parts, and additives are 1˜10 parts.

The material of the first planarization layer 19 may include propylene glycol methyl ether acetate, acrylate monomer, zirconium dioxide particles, 1-methoxy-2-propanol, (3-methoxy-1-butyl) acetate, metal oxide particles, photoinitiator, coupling agent and additives; wherein propylene glycol methyl ether acetate is 20 to 30 parts, acrylate monomer is 1 to 10 parts, zirconium dioxide particles are 20 to 30 parts, 1-methoxy-2-propanol is 10 to 20 parts, (3-methoxy-1-butyl) acetate is 10 to 20 parts, metal oxide particles are 0.1 to 3 parts, photoinitiator is 0.1 to 3 parts, coupling agent is 1 to 5 parts, and additives are 1 to 10 parts.

It should be noted that the parts of the above-mentioned various materials are all parts by weight.

In this exemplary embodiment, the transmittance of the light extraction layer 18 is greater than the transmittance of the first planarization layer 19. Specifically, the transmittance of the light extraction layer 18 may be greater than or equal to 96%, and the transmittance of the first planarization layer 19 may be greater than or equal to 90%.

In this example embodiment, the modulus of the first planarization layer is greater than 1000 KPa.

In some other exemplary embodiments of the present disclosure, the material of the first planarization layer 19 may be PSA (Pressure Sensitive Adhesive) or OCA (Optically Clear Adhesive); the modulus of the first planarization layer 19 prepared from these two materials is less than or equal to 200 Kpa, the thickness of the first planarization layer 19 prepared from these two materials is greater than or equal to 10 microns and less than or equal to 50 microns, the transmittance is greater than or equal to 95%, and the refractive index is greater than or equal to 1.65. The first planarization layer 19 prepared from these two materials can be made into a film first, and then attached to the light-emitting side of the light extraction layer 18 away from the display substrate 100.

The specific structures and principles of the light extraction layer 18 and the first planarization layer 19 are described above. The positions of the light extraction layer 18 and the first planarization layer 19 are described in detail below through several example implementations.

Referring further to FIG. 8, an encapsulation layer group 14 is disposed on the side of the second electrode 13 away from the base substrate 1. The encapsulation layer group 14 can be multi-layered and can include an organic layer and an inorganic layer. The specific materials and number of layers are not described here.

The touch layer group 15 is disposed on the light-exiting side of the display substrate 100. Specifically, the touch layer group 15 is disposed on the side of the encapsulation layer group 14 away from the display substrate 100. The touch layer group 15 may include a first touch metal layer 151, a touch insulating layer 152, and a second touch metal layer 153. The first touch metal layer 151 is disposed on the light-exiting side of the display substrate 100. Specifically, the first touch metal layer 151 is disposed on the side of the encapsulation layer group 14 away from the base substrate 1; the touch insulating layer 152 is disposed on the side of the first touch metal layer 151 away from the display substrate 100. The second touch metal layer 153 is disposed on the side of the touch insulating layer 152 away from the display substrate 100.

In this example embodiment, the touch insulating layer 152 can be multiplexed as the light extraction layer 18, that is, the touch insulating layer 152 can not only play the role of insulating and isolating the first touch metal layer 151 and the second touch metal layer 153, but also play the role of the light extraction layer 18 to fully reflect the light; and it can reduce one mask process, improve efficiency and reduce costs.

The refractive index of the touch insulating layer 152 is greater than or equal to 1.4 and less than or equal to 1.55. That is, the refractive index of the light extraction layer 18 is greater than or equal to 1.4 and less than or equal to 1.55.

In this exemplary embodiment, the first touch metal layer 151 and the second touch metal layer 153 form a touch pattern, and the touch pattern may include a plurality of metal lines, and the plurality of metal lines are connected to form a grid shape, so the orthographic projection of the touch pattern on the base substrate 1 is also in a grid shape. A gap is provided between two adjacent first grooves 181, and the orthographic projection of the metal line on the display substrate 100 is located within the orthographic projection of the gap on the display substrate 100. The sub-pixel 20 is also located within the grid of the orthographic projection of the touch pattern on the base substrate 1, and the sub-pixel 20 is in a one-to-one correspondence with the first groove 181 and the second groove 191. The metal lines of the first touch metal layer 151 and the second touch metal layer 153 are prevented from affecting the light extraction efficiency.

The touch layer group 15 may further include a protective layer 154, which is disposed on a side of the second touch metal layer 153 away from the display substrate 100. The protective layer 154 may be multiplexed as the first planarization layer 19, that is, the protective layer 154 may not only protect the second touch metal layer 153, but also serve as the first planarization layer 19 to refract light; moreover, the mask process may be reduced once, thereby improving efficiency and reducing costs.

Of course, in some other exemplary embodiments of the present disclosure, the protective layer 154 may also be multiplexed as the light extraction layer 18, and a first planarization layer 19 is further provided on a side of the protective layer 154 away from the base substrate 1.

The thickness of the first planarization layer 19 is greater than or equal to 2 micrometers and less than or equal to 5 micrometers. The first planarization layer 19 is thin, which is conducive to the bending of the display panel, so that the technology can be applied to flexible display panels.

It should be noted that the thickness of the first planarization layer 19 refers to the thickness at the thickest part of the first planarization layer 19, for example, it may be the thickness H5 of the first planarization layer 19 at the second groove 191.

The refractive index of the first planarization layer 19 is greater than or equal to 1.6 and less than or equal to 1.75. For example, the refractive index of the first planarization layer 19 may be 1.67, 1.69, etc. Further, the refractive index of the first planarization layer 19 is greater than or equal to 1.7 and less than or equal to 1.75. For example, the refractive index of the first planarization layer 19 may be 1.72, 1.74, etc.

The display panel may further include a second planarization layer 23. The second planarization layer 23 is disposed on a side of the first planarization layer 19 away from the display substrate 100. A side of the second planarization layer 23 away from the display substrate 100 is a plane.

In this example embodiment, the display panel may further include an adhesive layer 16 and a cover plate 17; the adhesive layer 16 is disposed on a side of the first planarization layer 19 away from the display substrate 100, and the adhesive layer 16 is multiplexed as the second planarization layer 23; the cover plate 17 is disposed on a side of the adhesive layer 16 away from the display substrate 100; that is, the adhesive layer 16 bonds the cover plate 17 to the touch layer group 15.

The material of the adhesive layer 16 can be OCA (Optically Clear Adhesive). The refractive index of OCA is less than the refractive index of the first planarization layer 19, that is, the refractive index of the adhesive layer 16 is less than the refractive index of the first planarization layer 19, and the refractive index of the adhesive layer 16 is greater than or equal to 1.4 and less than or equal to 1.45. Referring to FIGS. 3 and 5, when the refractive index of the adhesive layer 16 is less than the refractive index of the first planarization layer 19, the light that is totally reflected by the groove sidewall of the first groove 181 will be refracted by the groove sidewall of the second groove 191, so that the refracted light can be emitted substantially perpendicular to the display surface of the display substrate 100. The adhesive layer 16 cooperates with the first planarization layer 19 to improve the light extraction efficiency. The thickness of the adhesive layer 16 is greater than or equal to 50 microns and less than or equal to 150 microns.

Of course, in other example embodiments of the present disclosure, the refractive index of the adhesive layer 16 may be greater than the refractive index of the first planarization layer 19. In this case, the interface between the adhesive layer 16 and the first planarization layer 19 will not form a total reflection interface, and the light that is totally reflected by the side wall of the first groove 181 will be refracted by the side wall of the second groove 191, so that the refracted light can be emitted basically perpendicular to the display surface of the display substrate 100.

In addition, it should be noted that due to the long extension length of the groove side wall of the second groove 191, a part of the light does not undergo the total reflection of the groove side wall of the first groove 181, and directly incident to the groove side wall of the second groove 191 and is refracted at the groove side wall of the second groove 191. Since the refractive index of the first planarization layer 19 is smaller than the refractive index of the adhesive layer 16, the light is incident from the optically sparse medium into the optically dense medium, and the refraction angle is smaller than the incident angle, so that the obliquely incident light is refracted to the front of the display panel, thereby improving the light output efficiency of the front of the display panel.

The inclination angle of the second groove 191 can be calculated by the formula n1×sin α1=n2×sin α2 (where n1 is the refractive index of the incident side medium, α1 is the incident angle of the light, n2 is the refractive index of the refractive side medium, and α2 is the refraction angle of the light).

The adhesive layer 16 is formed on the side of the first planarization layer 19 away from the display substrate 100 by coating, spin coating and other processes. The adhesive layer 16 has a certain fluidity, so that the side of the adhesive layer 16 away from the display substrate 100 is flat, so that the cover plate 17 and the adhesive layer 16 can be well bonded, avoiding the generation of bubbles between the cover plate 17 and the adhesive layer 16, which affects the light output effect.

Of course, in some other exemplary embodiments of the present disclosure, other layers may be disposed on the side of the first planarization layer 19 away from the display substrate 100.

It should be noted that it is preferable to minimize the distance between the light extraction layer 18 and the sub-pixel 20 in the second direction. Since the angle of light emission is constant, the farther away from the sub-pixel 20, the more scattered the light is, which is not conducive to total reflection of more light. It is preferable for the extension length of the groove sidewall of the second groove 191 to be as long as possible. This will not only not affect the light emission from the front, but also refract more light to the front of the display panel, thereby improving the light emission efficiency from the front.

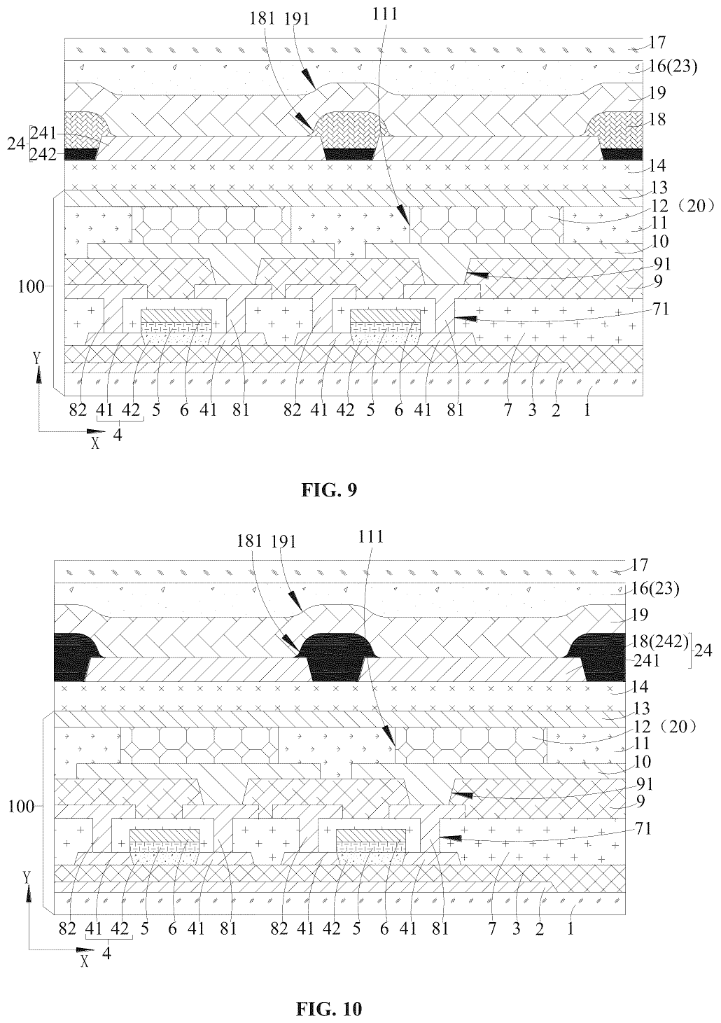

In addition, in some other example embodiments of the present disclosure, as shown in FIG. 9, when the light emitted by the sub-pixel 20 is white light, the display panel may further include a color filter layer 24, and the color filter layer 24 is disposed on a side of the encapsulation layer group 14 away from the display substrate 100. The color filter layer 24 may include a black matrix 242 and a filter portion 241, and the filter portion 241 may include a red filter portion, a green filter portion and a blue filter portion. The red filter portion transmits red light, the green filter portion transmits green light, and the blue filter portion transmits blue light.

The height of the black matrix 242 in the second direction Y is smaller than the height of the filter 241 in the second direction Y. The light extraction layer 18 is disposed on the side of the color filter layer 24 away from the display substrate 100. Specifically, the light extraction layer 18 is disposed on the side of the black matrix 242 away from the display substrate 100; the first planarization layer 19 is disposed on the side of the light extraction layer 18 away from the color filter layer 24. Of course, a touch layer group 15 may also be disposed between the color filter layer 24 and the encapsulation layer group 14, and its specific structure will not be described in detail here.

Referring to FIG. 10, in some further exemplary embodiments of the present disclosure, the edge of the black matrix 242 covers the edge of the filter 241. The above structure can be achieved by first preparing the filter 241 and then forming the black matrix 242. The height of the black matrix 242 in the second direction Y is greater than the height of the filter 241 in the second direction Y. The black matrix 242 is multiplexed as the light extraction layer 18. Specifically, the portion of the black matrix 242 protruding from the filter 241 is multiplexed as the light extraction layer 18. This arrangement can reduce one step of the mask process, improve efficiency and reduce costs. A first planarization layer 19 is formed on the side of the color filter layer 24 away from the display substrate 100. The refractive index of the first planarization layer 19 is greater than the refractive index of the black matrix 242, which can also achieve the effect of improving the light extraction efficiency of the front side of the display panel.

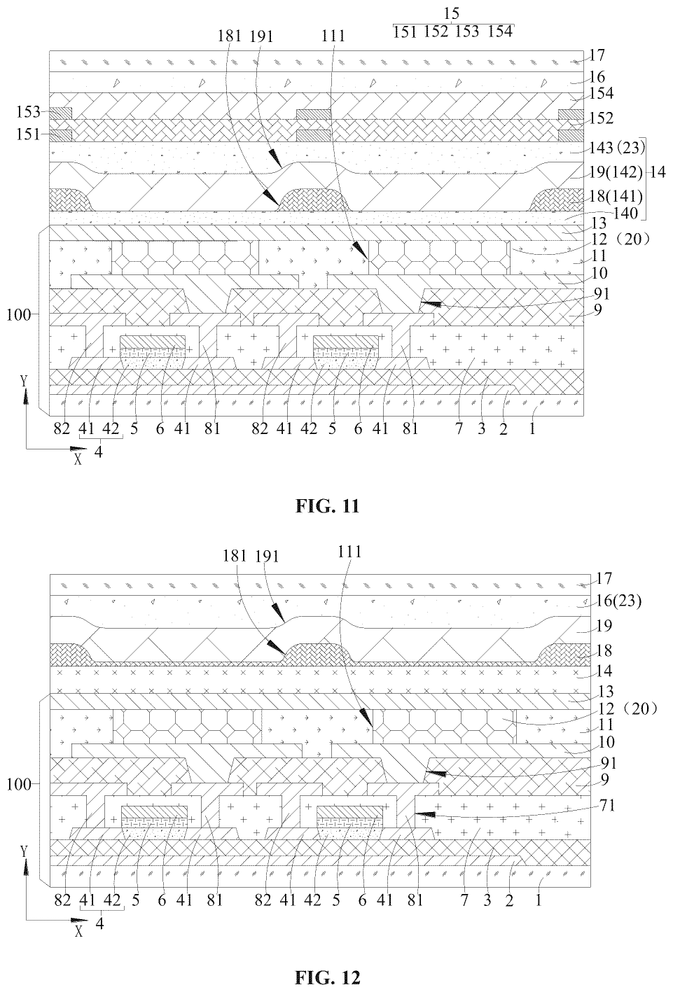

Referring to FIG. 11, in some other example embodiments of the present disclosure, the encapsulation layer group 14 may include an encapsulation base layer 140, a first encapsulation layer 141, a second encapsulation layer 142, and a third encapsulation layer 143.

The encapsulation base layer 140 is disposed on the light emitting side of the display substrate 100. The encapsulation base layer 140 may be made of silicon nitride (SiNx), silicon oxide (SiOx), or the like.

The first encapsulation layer 141 is disposed on a side of the encapsulation base layer 140 away from the display substrate 100.

In this example embodiment, a first groove 181 is provided on the first encapsulation layer 141, and the first encapsulation layer 141 can be multiplexed as the light extraction layer 18, that is, the first encapsulation layer 141 can not only play the role of encapsulating the display substrate 100, but also play the role of the light extraction layer 18 for total reflection of light; and it can reduce one mask process, improve efficiency and reduce cost.

The second encapsulation layer 142 is disposed on a side of the first encapsulation layer 141 away from the display substrate 100; the refractive index of the second encapsulation layer 142 is greater than the refractive index of the first encapsulation layer 141.

In this example embodiment, a second groove 191 is provided on the second encapsulation layer 142, and the second encapsulation layer 142 can be multiplexed as the first planarization layer 19, that is, the second encapsulation layer 142 can not only play the role of encapsulating the display substrate 100, but also play the role of the first planarization layer 19 in refracting light; and it can reduce one mask process, thereby improving efficiency and reducing costs.

Since the refractive index of the planarization layer 19 is greater than the refractive index of the light extraction layer 18, the light emitted from the planarization layer 19 to the light extraction layer 18 in the first groove 181 is emitted from the optically dense medium into the optically sparse medium. For incident light with an incident angle greater than a certain critical angle (i.e., the light far away from the normal), the refracted light will disappear and the incident light will be reflected without entering the light extraction layer 18, resulting in total reflection, so that the inclined light is emitted from the front of the display panel, thereby improving the light extraction efficiency of the display panel.

The third encapsulation layer 143 is disposed on a side of the second encapsulation layer 142 away from the display substrate 100. The material of the third encapsulation layer 143 may be silicon nitride (SiNx) or silicon nitride oxide (SiNO), etc. The refractive index of the third encapsulation layer 143 is greater than or equal to 1.70 and less than or equal to 1.85. The third encapsulation layer 143 is formed on a side of the second encapsulation layer 142 away from the display substrate 100 by chemical vapor deposition (CVD), and a portion of the third encapsulation layer 143 is formed in the second groove 191. The third encapsulation layer 143 can be multiplexed as the second planarization layer 23.

Since the refractive index of the third encapsulation layer 143 is greater than the refractive index of the second encapsulation layer 142, the light incident from the second encapsulation layer 142 to the third encapsulation layer 143 is incident from the optically sparse medium to the optically dense medium, and no total reflection occurs. The light totally reflected by the groove sidewall of the first groove 181 will be refracted by the groove sidewall of the second groove 191, so that the refracted light can be emitted substantially perpendicular to the display surface of the display substrate 100. The third encapsulation layer 143 can be multiplexed as the third light extraction layer 23.

A first touch metal layer 151, a touch insulating layer 152, a second touch metal layer 153, a protective layer 154, an adhesive layer 16 and a cover plate 17 are sequentially stacked on a side of the third encapsulation layer 143 away from the display substrate 100, and the specific structure thereof has been described in detail above, so it will not be repeated here.

Of course, in some other example embodiments of the present disclosure, the light extraction layer 18 and the first planarization layer 19 can be provided separately, and their specific positions can be provided between the touch layer group 15 and the encapsulation layer group 14, or on the side of the touch layer group 15 away from the display substrate 100, and so on; they can also be provided at other positions, which will not be elaborated here.

It should be noted that no matter where the light extraction layer 18 and the first planarization layer 19 are arranged, the first planarization layer 19 can be basically formed into a plane on a side away from the display substrate 100, that is, the second groove 191 may not be formed in the first planarization layer 19.

Based on the same inventive concept, an exemplary embodiment of the present disclosure provides a method for manufacturing a display panel, as shown in FIG. 14, the manufacturing method may include the following steps:

Step S10: forming a display substrate, wherein the display substrate includes a plurality of sub-pixels.

Step S20: forming a light extraction layer on the light emitting side of the display substrate, wherein the light extraction layer includes a plurality of first grooves.

Step S30, forming a first planarization layer on a side of the light extraction layer away from the display substrate, wherein the refractive index of the first planarization layer is greater than the refractive index of the light extraction layer, and the thickness of the first planarization layer is 1.5 to 5 times greater than the thickness of the light extraction layer.

Hereinafter, respective steps of the method for manufacturing the display panel are described in detail.

Step S10: forming a display substrate, wherein the display substrate includes a plurality of sub-pixels.

In this example embodiment, a base substrate 1 is provided, and a light shielding layer 2 and a buffer layer 3 are formed on one side of the base substrate 1; a thin film transistor including an active layer 4, a gate 6, a source 81 and a drain 82 is formed on a side of the buffer layer 3 away from the base substrate; and then a light-emitting device including a first electrode 10, a pixel definition layer 11, a light-emitting layer group 12 and a second electrode 13 is formed on a side of the thin film transistor away from the base substrate 1.

Step S20: forming a light extraction layer on the light emitting side of the display substrate, wherein the light extraction layer includes a plurality of first grooves.

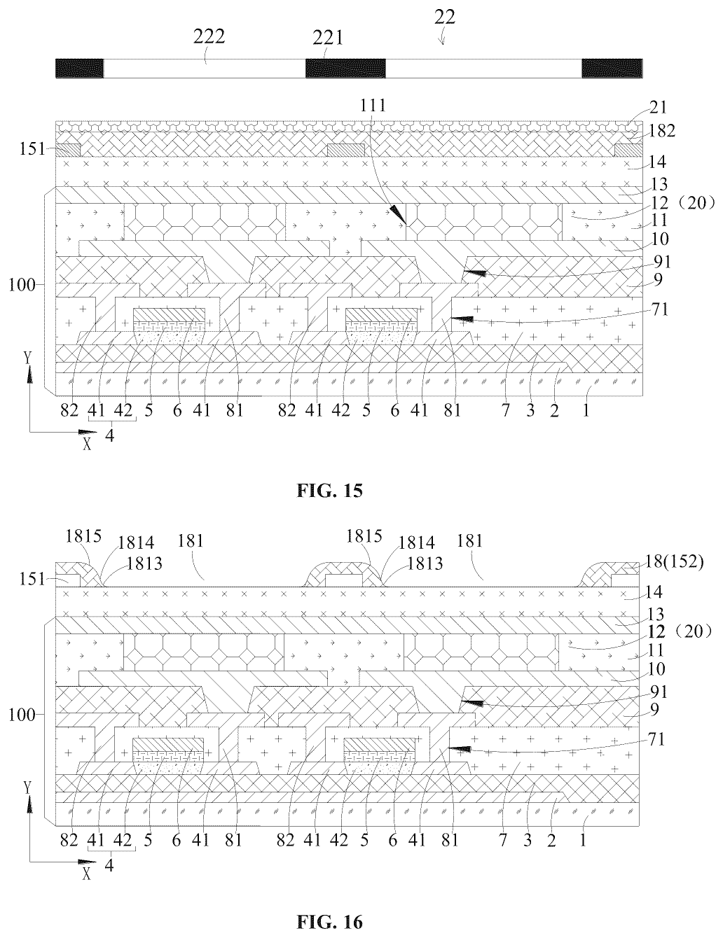

In this exemplary embodiment, as shown in FIG. 15, a light extraction material layer 182 is formed on the light emitting side of the display substrate 100 by coating or other processes, a photoresist 21 is coated on the side of the light extraction material layer 182 away from the base substrate, a mask plate 22 is placed on the side of the photoresist 21 away from the base substrate, and the mask plate 22 may include a light shielding portion 221 and a light transmitting portion 222, the light transmitting portion 222 is aligned to the sub-pixel 20, and the remaining portion is arranged corresponding to the light shielding portion 221, and then light is irradiated, and finally the photoresist 21 is developed to remove the photoresist 21 aligned to the light transmitting portion 222. As shown in FIG. 16, the light extraction material layer 182 is etched with the remaining photoresist 21 as a mask layer to remove a portion of the exposed light extraction material layer 182 to form a first groove 181, and the light extraction material layer 182 covered by the photoresist 21 forms a light extraction layer 18, and the thickness of the light extraction layer 18 is greater than or equal to 1 micron and less than or equal to 3 microns.

The light extraction material layer 182 is in liquid form when coated on the light emitting side of the display substrate 100, and the liquid viscosity of the light extraction material layer 182 is less than or equal to 5 cp, so that the thickness of the light extraction material layer 182 can be made thinner.

It should be noted that the etching depth of the first groove 181 can be adjusted by the length of the etching time, that is, whether the first groove 181 is formed as a via hole that passes through the light extraction layer 18 or a blind hole can be adjusted by the length of the etching time. The longer the etching time is, the greater the depth of the first groove 181 will be.

Of course, the light extraction layer 18 can also be formed by other methods, for example, the photoresist can be exposed and developed by an automatic photolithography machine, without the need to place the mask plate 22, and the specific process will not be repeated here.

It should be noted that the photolithography of the light extraction material layer 182 is not only to form the first groove 181, but also to remove the light extraction material layer in the bending area ZW and the binding area BOD, and to form a spacing space between two adjacent display panels.

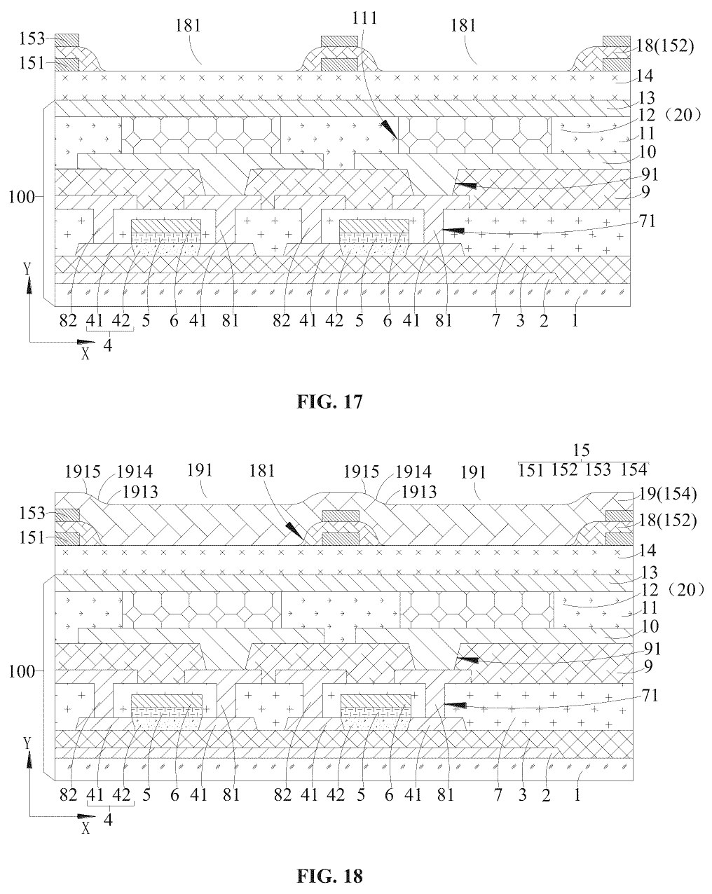

Referring to FIG. 17, a second touch metal layer 153 is formed on a side of the light extraction layer 18 away from the base substrate 1.

In step S30, a first planarization layer is formed on a side of the light extraction layer away from the display substrate, wherein the refractive index of the first planarization layer is greater than the refractive index of the light extraction layer, and the thickness of the first planarization layer is 1.5 to 5 times greater than the thickness of the light extraction layer.

In this example embodiment, a first planarization material layer is formed by a coating process on the side of the light extraction layer 18 away from the display substrate 100, and the first planarization material layer is photolithographed to form the first planarization layer 19. The photolithography process is the same as the above-mentioned photolithography process for the light extraction material layer 182, so it is not repeated here. Since the protective layer 154 is multiplexed as the first planarization layer 19, as shown in FIG. 18, the first planarization material layer is formed by a coating process on the side of the light extraction layer 18 away from the display substrate 100, that is, a protective layer 154 is formed by coating, spin coating, and the like on the side of the light extraction layer 18 and the second touch metal layer 153 away from the base substrate 1.

It should be noted that the photolithography of the first planarization material layer is mainly to remove the first planarization material layer in the bending area ZW and the binding area BOD and the first planarization material between two adjacent display panels to form the first planarization layer 19.

The liquid viscosity of the planarization material layer is less than or equal to 5 cp. Viscosity is a measure of fluid viscosity and an expression of the fluid flow force on its internal friction phenomenon. A large viscosity indicates a large internal friction. The planarization material layer with a small viscosity has good fluidity, and it is easy to planarize the first groove 181, so that the flatness of the first planarization layer 19 away from the base substrate 1 reaches more than 85%.

Therefore, compared with the related art, in which the viscosity of the first planarization material layer is greater than 20 cp, the first planarization layer 19 can be made thinner, which can achieve the planarization effect and meet the bending requirements of the flexible display panel.

It should be noted that, although the steps of the method for manufacturing the display panel in the present disclosure are described in a specific order in the accompanying drawings, this does not require or imply that the steps must be performed in this specific order, or that all the steps shown must be performed to achieve the desired result. Additionally or alternatively, some steps may be omitted, multiple steps may be combined into one step, and/or one step may be divided into multiple steps, etc.

Based on the same inventive concept, an exemplary embodiment of the present disclosure provides a display device, which may include any of the above-mentioned display panels. The specific structure of the display panel has been described in detail above, so it will not be repeated here.

The specific type of the display device is not particularly limited, which may be any type of display device commonly used in the field, such as mobile devices such as mobile phones, wearable devices such as watches, VR devices, etc. Those skilled in the art can make corresponding choices based on the specific purpose of the display device, which will not be described in detail here.

It should be noted that, in addition to the display panel, the display device also includes other necessary components and parts, such as a housing, a circuit board, a power cord, etc., taking the display as an example, those skilled in the art can make corresponding supplements according to the specific use requirements of the display device, which will not be described in detail here.

Compared with the prior art, the beneficial effects of the display device provided by the exemplary embodiment of the present invention are the same as the beneficial effects of the display panel provided by the above exemplary embodiment, which will not be described in detail herein.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising:
a display substrate comprising a plurality of sub-pixels;
a light extraction layer, disposed on a light emitting side of the display substrate, the light extraction layer comprising a plurality of first grooves; and
a first planarization layer, disposed on a side of the light extraction layer away from the display substrate, wherein a refractive index of the first planarization layer is greater than a refractive index of the light extraction layer, and a thickness of the first planarization layer is 1.5 to 5 times greater than a thickness of the light extraction layer.

2. (canceled)

3. The display panel according to claim 1, wherein the first planarization layer comprises a plurality of second grooves, the sub-pixel is covered by an orthographic projection of the first groove on the display substrate, and an orthographic projection of the second groove on the display substrate is at least partially overlapped with the orthographic projection of the first groove on the display substrate.

4. The display panel according to claim 3, wherein a height in a second direction of a groove sidewall of the first groove is increased with the increasing distance in a first direction from the center of the sub-pixel; and a height in the second direction of a groove sidewall of the second groove is increased with the increasing distance in the first direction from the center of the sub-pixel; wherein the second direction is perpendicular to a display surface of the display substrate, and the first direction is parallel to the display surface of the display substrate.

5. The display panel according to claim 4, wherein the groove sidewall of the first groove comprises a curved surface, the groove sidewall of the second groove comprises a curved surface, and a curvature radius of the groove sidewall of the first groove is smaller than a curvature radius of the groove sidewall of the second groove.

6. The display panel according to claim 5, wherein the groove sidewall of the first groove comprises a first portion, a second portion and a third portion which are smoothly connected in sequence, the first portion is closer to the display substrate than the third portion, the first portion and the third portion are configured as arc surfaces, and the second portion is configured as an inclined surface; and the groove sidewall of the second groove comprises a fourth portion, a fifth portion and a sixth portion which are smoothly connected in sequence, the fourth portion is closer to the display substrate than the sixth portion, the fifth portion is configured as an inclined surface, and the fourth portion and the sixth portion are configured as arc surfaces.

7. The display panel according to claim 6, wherein an inclination angle of the second portion is greater than an inclination angle of the fifth portion.

8. The display panel according to claim 4, wherein the groove sidewall of the first groove is configured as an inclined surface, the groove sidewall of the second groove is configured as an inclined surface, and an inclination angle of the groove sidewall of the first groove is greater than an inclination angle of the groove sidewall of the second groove.

9. The display panel according to claim 4, wherein an orthographic projection of the groove sidewall of the first groove on the display substrate is located within an orthographic projection of the groove sidewall of the second groove on the display substrate; and
a bottom wall of the first groove is a plane, a bottom wall of the second groove is a plane, the sub-pixel is covered by an orthographic projection of the bottom wall of the second groove on the display substrate, and the orthographic projection of the bottom wall of the second groove on the display substrate is located within an orthographic projection of the bottom wall of the first groove on the display substrate.

10. The display panel according to claim 3, wherein a depth of the first groove is greater than a depth of the second groove.

11. The display panel according to claim 10, wherein a thickness of the first planarization layer at the second groove is greater than a thickness of a portion of the first planarization layer opposite to the light extraction layer.

12.-15. (canceled)

16. The display panel according to claim 1, wherein the light extraction layer and the first planarization layer comprise same organic material.

17.-18. (canceled)

19. The display panel according to claim 16, wherein the material of the first planarization layer comprises propylene glycol methyl ether acetate, acrylate monomer, zirconium dioxide particles, 1-methoxy-2-propanol, (3-methoxy-1-butyl) acetate, metal oxide particles, photoinitiator, coupling agent and additives.

20. The display panel according to claim 19, wherein weight proportions of respective materials of the first planarization layer are: 20 to 30 parts of propylene glycol methyl ether acetate, 1 to 10 parts of acrylate monomer, 20 to 30 parts of zirconium dioxide particles, 10 to 20 parts of 1-methoxy-2-propanol, 10 to 20 parts of (3-methoxy-1-butyl) acetate, 0.1 to 3 parts of metal oxide particles, 0.1 to 3 parts of photoinitiator, 1 to 5 parts of coupling agent, and 1 to 10 parts of additives.

21.-23. (canceled)

24. The display panel according to claim 1, wherein the display panel further comprises:
an encapsulation layer group, disposed on the light emitting side of the display substrate; and
a touch layer group, disposed on a side of the encapsulation layer group away from the display substrate;
wherein, one layer in the encapsulation layer group or the touch layer group is multiplexed as the light extraction layer, and one layer in the encapsulation layer group or the touch layer group is multiplexed as the first planarization layer.

25. The display panel according to claim 24, wherein the touch layer group comprises:
a first touch metal layer, disposed on the light emitting side of the display substrate;
a touch insulating layer, disposed on a side of the first touch metal layer away from the display substrate;
a second touch metal layer is disposed on a side of the touch insulating layer away from the display substrate; and
a protective layer, disposed on a side of the second touch metal layer away from the display substrate;
wherein, the touch insulating layer is multiplexed as the light extraction layer.

26. The display panel according to claim 25, wherein the protective layer is multiplexed as the light extraction layer, or the protective layer is multiplexed as the first planarization layer.

27. (canceled)

28. The display panel according to claim 1, wherein the display panel further comprises:
a color filter layer, disposed on the light emitting side of the display substrate, wherein the color filter layer comprises a black matrix and a filter portion, and the black matrix is multiplexed as the light extraction layer.

29. The display panel according to claim 1, wherein the display panel further comprises:
a second planarization layer, disposed on a side of the first planarization layer away from the display substrate, and a side of the second planarization layer away from the display substrate is a plane;
an adhesive layer, disposed on the side of the first planarization layer away from the display substrate, the adhesive layer being multiplexed as the second planarization layer; and
a cover plate, disposed on a side of the adhesive layer away from the display substrate.

30. (canceled)

31. A method for manufacturing display panel, comprising:
forming a display substrate, the display substrate comprising a plurality of sub-pixels;
forming a light extraction layer on a light exiting side of the display substrate, wherein the light extraction layer comprises a plurality of first grooves; and
forming a first planarization layer on a side of the light extraction layer away from the display substrate, a refractive index of the first planarization layer is greater than a refractive index of the light extraction layer, and a thickness of the first planarization layer is 1.5 to 5 times greater than a thickness of the light extraction layer.

32.-35. (canceled)

36. A display device, comprising: a display panel, wherein the display panel comprises:
a display substrate comprising a plurality of sub-pixels;
a light extraction layer, disposed on a light emitting side of the display substrate, the light extraction layer comprising a plurality of first grooves; and
a first planarization layer, disposed on a side of the light extraction layer away from the display substrate, wherein a refractive index of the first planarization layer is greater than a refractive index of the light extraction layer, and a thickness of the first planarization layer is 1.5 to 5 times greater than a thickness of the light extraction layer.
